(19) United States
(12) Patent Application Publication
(10) Pub. No.: US 2009/0223440 A1
(43) Pub. Date: Sep. 10, 2009

(54) Method of growing GaN crystals from solution

(76) Inventors: Boris Feigelson, Springfield, VA (US); Rachel M. Frazier, Tuscaloosa, AL (US)

Correspondence Address: NAVAL RESEARCH LABORATORY;ASSOCIATE COUNSEL (PATENTS), CODE 1008.2, 4555 OVERLOOK AVENUE, S.W., WASHINGTON, DC, 20375-5320, US

(21) Appl. No.: 12/073,370

(22) Filed: Mar. 4, 2008

(51) Int. Cl. C30B 19/00

(52) U.S. Cl. 117/56

(57) ABSTRACT

A process for making gallium nitride crystals comprising the steps of charging a reaction vessel with a layer of one selected from a Group IA element nitride, a Group IIA element nitride, and combinations thereof, adding a layer of gallium, applying nitrogen pressure to prevent dissociation or decomposition, forming in situ a gallium nitride source by heating the charged reaction vessel to render the one selected from the group reacted with the gallium, forming in situ a solvent comprising the gallium and the one selected from the group released by an exchange reaction between the gallium and the one selected from the group, providing a temperature when formed gallium nitride will be dissolved in the formed solvent and providing a temperature difference in the solvent between the formed gallium nitride source and the growing single crystal gallium nitride, and growing a single crystal gallium nitride.

The present invention relates to a process for growing bulk monocrystalline gallium nitride (GaN) from solution. In particular, the invention relates to the method for growing GaN single crystals by recrystallizing GaN from a solution with (applying) temperature gradient at moderate pressures and temperatures.

Nitrides of In, Ga, and Al and their compounds are used in both high power and light emitting devices. However, the efficiency of these devices is hampered by vertical shorts stemming from defects which propagate from the substrate into device active layers and often originate from heteroepitaxial growth. The need and importance (benefit) of using low defect GaN monocrystalline material as a native substrate for further progress in III-N device applications is described elsewhere.

One of the techniques presently used for production of gallium nitride substrates is hydride vapor-phase epitaxy, which has been used to grow GaN wafers up to about 2 inches in diameter. The dislocation density of the best of such samples is approximately 10⁵/cm².

Another known technique for single-crystal growth involves deposition of gallium nitride from a liquid phase. Growth from the liquid phase has resulted in gallium nitride single crystals with dislocation densities of less than 10²/cm². Some of the liquid phase techniques are done using high pressures and high temperatures. High nitrogen pressure counters the gallium nitride decomposition that occurs above 1500° C. required to dissolve nitrogen in gallium. These high-pressure/high-temperature techniques have been used to grow gallium nitride crystal platelets of up to 1.5 cm in lateral size. Since crystal growth requires pressures on the order of 10 kbar or more and the rates of crystal growth are low, the routine growth of 2 inch-diameter wafers on a production scale is a daunting challenge for the high temperature high pressure techniques.

Gallium nitride has also been grown at lower temperatures/pressures by a sodium flux method. This flux method uses elemental gallium, gaseous nitrogen and either elemental sodium metal or sodium with additives of alkali or alkaline earth metals to increase reactivity and solubility of nitrogen in gallium. In the sodium flux method, the gaseous nitrogen reacts with the flux/elemental gallium to saturate the solution and deposit crystals. For these flux techniques, it has been difficult to establish and control growth of large gallium nitride crystals because the composition of the melt is not well controlled.

Small gallium nitride crystals have been grown in supercritical ammonia NH₃ in pressure vessels. These supercritical ammonia growth processes exhibit slow growth rates, and thus do not enable commercial production of large gallium nitride crystals. Also, the pressure vessels limit these gallium nitride growth processes and it is difficult to maintain the purity of the grown crystals.

The known gallium nitride crystal production processes are not believed to provide an economical process that enable moderate-cost low defect density and high purity gallium nitride crystal production.

Therefore, a gallium nitride crystal growth process that produces large gallium nitride crystals of high quality is needed. Further, a gallium nitride crystal growth process that can produce moderate cost large gallium nitride crystals of high quality is needed.

This invention provides improved control over Group III nitrides, particularly gallium nitride, single crystal growth.

This invention can be used to prepare single crystal gallium nitride (GaN) at moderate temperature and near atmospheric pressure.

This invention can be used to use GaN as a feedstock (source) to grow single crystal GaN on a seed at near atmospheric pressure in a process characterized by a temperature gradient or a temperature difference.

This invention can grow a GaN single crystal using GaN as a source, prepared in situ during the same growth run—self-developing process.

This invention can use a source prepared in situ during the same growth run and using a solvent prepared in situ during the same growth run to dissolve GaN feedstock and to grow single crystal GaN—self-developing process.

This invention can be used to grow single crystal gallium nitride of a large size exceeding about one inch.

This invention can be used to grow commercial size and commercial grade single crystal gallium nitride for use in electronic devices.

This invention can grow single crystal gallium nitride by a moderate temperature and moderate pressure process with a dislocation density in the crystals of fewer than about 10⁴ dislocations per square centimeter.

These and other aspects of this invention can be accomplished by a process of growing single crystal gallium nitride at nitrogen pressure and temperature in the region of the phase diagram where gallium nitride is thermodynamically stable. This process includes using solid gallium nitride as a feedstock for growing single crystal gallium nitride from the solution by applying a temperature gradient. This gallium nitride feedstock is synthesized in situ during the same growth run (self-developing process, in situ source formation). Synthesized gallium nitride feedstock dissolves in the solvent, which is also produced in situ during the same growth run (self-developing process, in situ solvent formation), and then precipitates from the solution as a GaN crystal. By using solid GaN as a feedstock we eliminate the dissolution of gaseous nitrogen in a liquid, and thereby eliminate a change in the solution's composition during the growth of single crystal gallium nitride. In situ synthesized gallium nitride is porous with high surface area and simultaneously is high purity material. These combined properties of the in situ synthesized gallium nitride source are very beneficial for growth. High surface area of the in situ prepared gallium nitride promotes dissolution of the feedstock, and creates better growth conditions in terms of ease of feeding the solution with source gallium nitride or III-Nitride. Porous material with high surface area which is exposed to atmosphere is contaminated with oxygen and moisture which may be incorporated into the growing crystal. In situ prepared gallium nitride source is not exposed to atmosphere and is not contaminated with oxygen and moisture from the atmosphere. By using the disclosed proper solvent, prepared in situ during the same growth run, gallium nitride source can be dissolved at moderate pressure and moderate temperature and then the gallium nitride crystal grows from the self developed (created) solution at moderate pressure and near atmospheric temperature.

In practice this invention includes the steps of selecting components for a reactor to provide a predetermined temperature gradient under operating conditions and assembling these components and enclosing a reaction vessel and charge therein. This charge includes (1) a Group IA or/and Group IIA element nitride (an alkali metal or/and alkaline earth metal nitride) layer located in a region of the reaction vessel, which under growth conditions will have a temperature at or near the high end of the temperature gradient, and (2) a layer of gallium or composition of gallium with an alkali metal or/and alkaline earth metal interposed between the Group IA or/and Group IIA nitride and the deposition site, and (3) also may include at least one seed crystal located in the deposition site (a region of the reaction vessel, which under growth conditions will have a temperature at or near the low end of the aforementioned temperature gradient); simultaneously subjecting the reaction vessel and the charge therein both to pressure and temperature in the gallium nitride-stable region of the phase diagram of gallium nitride and first to heat to a temperature of the reaction point between a Group IA or/and Group IIA nitride and gallium, whereby Group IA or/and Group IIA nitride and gallium are first reacted to substitute Group IA or/and Group IIA metal in nitride with gallium and formed gallium nitride feedstock (source), and at the same time the released Group IA or/and Group IIA element is mixed with residual gallium and forms a solvent for gallium nitride, then at the predetermined growth temperature and pressure the aforementioned formed gallium nitride feedstock is dissolved in the formed molten solvent within the hotter part of the reaction vessel, and precipitates from the solution to grow a single crystal either self seeded or on a seed if one (or more) was included in a cooler part of the reaction vessel.

### BRIEF DESCRIPTION OF THE DRAWINGS

FIG. 1 is a schematic cross sectional view showing an example of GaN growth reactor: (a) before the reaction, (b) after the reaction and growth.

FIG. 2 is a schematic cross sectional view showing an example of GaN growth reactor with seed located at the bottom of the reaction vessel (a) before the reaction, (b) after the reaction and growth.

FIG. 3 is a schematic cross sectional view of the growth reactor with the substrate at the bottom of the reaction vessel (a) before the reaction, (b) after the reaction and growth.

FIG. 4 is an optical image of (a) the seed—HVPE GaN polycrystalline aggregate before growth run, (b) the seed—HVPE GaN polycrystalline aggregate after growth run with grown GaN crystals, (c) and (d) zoomed images of the crystals shown on the FIG. 2c, arrow indicates m direction, (e) grown crystals are separated from the seed.

FIG. 5 is room temperature micro-Raman spectrum of the GaN crystal grown on the polycrystalline GaN seed in the backscatter geometry.

FIG. 6 is XRD rocking curve of the (0004) reflection for the GaN crystal grown on the polycrystalline GaN seed.

FIG. 7 is (a) low temperature PL spectra of crystals grown on polycrystalline aggregate seed, (b) reduction of yellow band in the grown crystals compared to the seed.

FIG. 8 is (a) image of the HVPE GaN template used as a seed with epitaxially grown GaN layer, (b) omega-2theta space map of the symmetric (0004) reflection for the (a) as-received GaN seed and (b) Ga-face of the GaN grown crystal.

### DETAILED DESCRIPTION

This disclosure pertains to a process for growing single crystal gallium nitride which process is characterized by the use of a solvent that dissolves gallium nitride feedstock or source of gallium nitride and the application of a temperature gradient to control dissolution of solid gallium nitride in the solvent and precipitation of gallium nitride from the solution on a seed or on another nucleation site to grow gallium nitride single crystal.

One essential part of the invention is the formation of the gallium nitride feedstock during the first stage of the growth run (self-developing process). The gallium nitride feedstock is formed by the exchange reaction of Group IA or/and Group IIA element (alkali metal or/and alkaline earth metal) nitride with gallium.

Another essential part of the invention is a solvent formation during the exchange reaction between Group IA or/and Group IIA element nitride and gallium (self-developing process). As a result of this reaction Group IA or/and Group IIA element is released and creates a compound with an initial composition. The new composition serves as a solvent for the GaN source.

More specifically, the process for growing single crystal gallium nitride includes the following steps. Group IA or/and Group IIA element nitride is placed in a region of the reaction vessel, which under operating conditions will have a temperature at or near the high end of the temperature gradient, and a layer of material comprised of gallium or gallium with alkali metal or/and alkaline earth metal composition interposed between the Group IA or/and Group IIA nitride and the deposition site (a region of the reaction vessel, which under operating conditions will have a temperature at or near the low end of the aforementioned temperature gradient), and also may include at least one seed crystal located within the deposition site. The reaction vessel with the charge is placed in the reactor filled with nitrogen, simultaneously subjecting the reaction vessel and the charge therein both to pressure and temperature in the gallium nitride-stable region of the phase diagram of gallium nitride. Pressure of nitrogen during the growth run is maintained in the range from 0.1 MPa to 20 MPa, but not limited to within this range. The charge is heated under nitrogen atmosphere to the temperature when the reaction between Group IA or/and Group IIA element nitride and gallium occurs. As a result of this exchange reaction part of the gallium replaces Group I and/or Group II element in the nitride and gallium nitride feedstock is created. Released from the nitride Group IA or/and Group IIA element is mixed with residual gallium or its said composition and forms a compound which serves as a solvent for gallium nitride source. The next step of the process is to maintain the growth temperature and pressure with a temperature gradient between the formed GaN feedstock and the nucleation site. The formed gallium nitride feedstock is dissolved by the solvent in a region of the reaction vessel, which under operating conditions has a temperature at or near the high end of the temperature gradient and said dissolved gallium nitride precipitates as a single gallium nitride crystal within the deposition site, which under operating conditions has a temperature at or near the low end of the aforementioned temperature gradient. The deposition site may have at least one GaN seed or the gallium nitride crystal can start to grow by spontaneous nucleation. The heat is kept for the time required to grow the desired gallium nitride crystal and then the heating step is discontinued.

The process involves the use of a Group IA (alkali metal) nitride or/and a Group IIA (alkaline earth metal) nitride. Of the alkali nitrides, lithium nitride is preferred.

The temperature gradient inside the molten solvent between the gallium nitride source (hotter region of reaction vessel) and the growing single crystal gallium nitride (cooler region of reaction vessel) promotes dissolution of the gallium nitride source, creating a supersaturated solution of gallium nitride in the solvent, and precipitation of the gallium nitride either on the coldest parts of the reaction vessel, containing the solution and the source of gallium nitride or on one or more seed crystals located in a deposition zone.

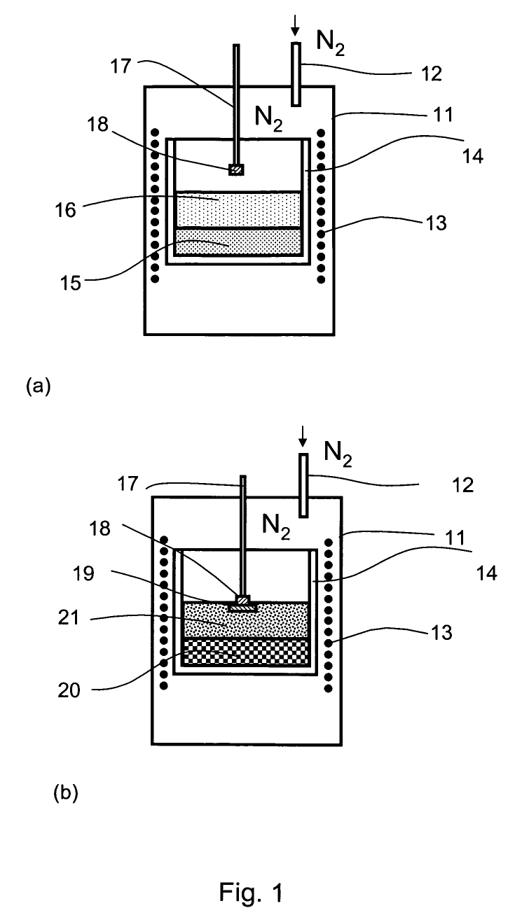

Disclosure of the process here is made in connection with the equipment, shown in FIG. 1a, b, where reactor 11 with nitrogen inlet 12 is shown containing furnace 13 with reaction vessel 14 disposed therein containing solid Group IA or/and Group IIA element nitride 15 at the bottom thereof and gallium or gallium with alkali metal or/and alkaline earth metal composition 16 disposed thereover. Optional holder 17 holding optional seed gallium nitride crystal 18 may be immersed in or in contact with the solvent 21. Operation of the equipment shown in FIG. 1 typically involves disposition of Group IA or/and Group IIA element nitride 15 and gallium or gallium with alkali metal or/and alkaline earth metal composition 16 in the reaction vessel 14, heating the charge to the temperature of the reaction between Group IA or/and Group IIA element nitride and gallium, creating gallium nitride source 20 and solvent 21 by exchange reaction of Group IA or/and Group IIA element nitride 15 with gallium 16, maintaining growth temperature and providing a temperature gradient whereby temperature of the solvent 21 (formed during the exchange reaction) nearby the gallium nitride source is higher than temperature of the molten solvent nearby the place where gallium nitride single crystal 19 is growing, all under pressure of a gas, containing nitrogen, in the reactor 11, precipitating single crystal gallium nitride 19 and cooling the charge.

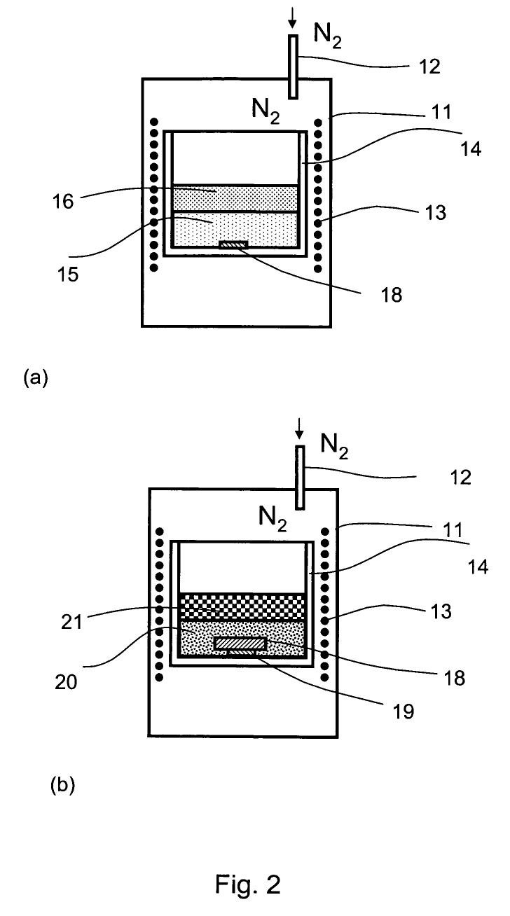

In another embodiment of this invention, shown in FIG. 2, a seed of gallium nitride 18 is placed at the bottom of the reaction vessel 14, covered with gallium or gallium with alkali metal or/and alkaline earth metal composition 16 and solid Group IA or/and Group IIA element nitride 15 disposed thereover. In this case, the gallium nitride source 21 is formed during the exchange reaction at the top of the charge located within the reaction vessel and solvent 20 is formed under the source, providing the temperature gradient has opposite direction compared to the previous embodiment, shown in FIG. 1.

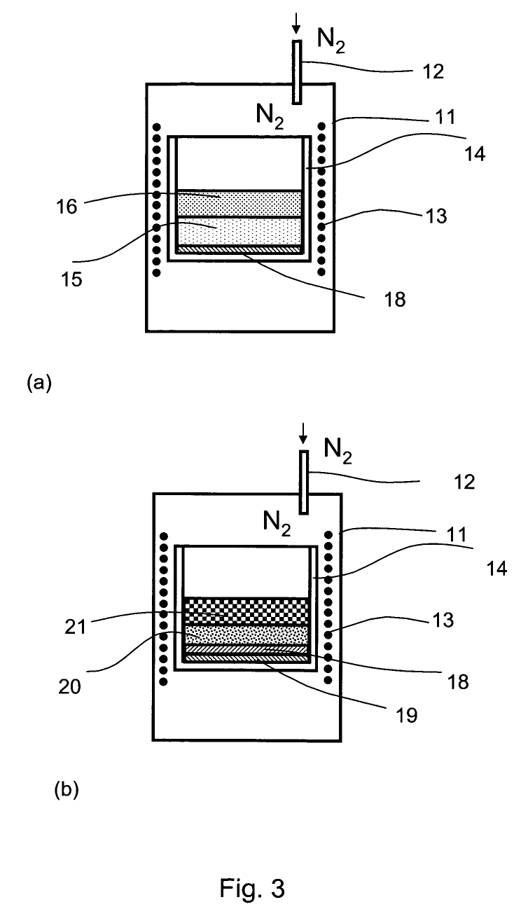

Instead of using a small gallium nitride seed, a gallium nitride template can be used as a substrate for growing a thick gallium nitride layer, as shown in FIG. 3.

During the process of gallium nitride growth, the formed solvent is in a molten state at a temperature in the range of 700-900° C., more typically 750-850° C. and the nitrogen pressure in the growth reactor is typically above atmospheric, more typically 0.1-1.0 MPa. The temperature gradient, i.e., the temperature difference inside the solvent between the gallium nitride source and the growing crystal, is typically 1-100° C. across the thickness of the solvent, and more typically 5-50° C.

In an embodiment of this process with a seed crystal, the seed crystal is typically the coldest spot in the reaction vessel within the reactor when precipitation of single crystal gallium nitride takes place. Due to the driving force imparted to the gallium nitride dissolved in the solvent, gallium nitride leaves the solvent when the solvent becomes supersaturated with gallium nitride and precipitates on the seed crystal, thereby growth of gallium nitride propagates on the seed crystal. If the process is carried out without the seed crystal, nucleation and growth of gallium nitride takes place within the colder parts of the reaction vessel containing the solvent. The resulting crystals typically have single crystal structure.

Having described the invention, the following examples are given as a particular embodiment thereof and to demonstrate the practice and advantages thereof. It is understood that the example is given by way of illustration and is not intended to limit the specification of the claims in any manner.

### EXAMPLE 1

This example demonstrates preparation of single crystal gallium nitride at moderate temperature and moderate pressure using lithium nitride and gallium in the set-up shown in FIG. 1 where the reaction vessel (crucible) 14 contained a lithium nitride pill 15 with the gallium 16 disposed thereover. All material preparations of the charge were carried out inside a glove box under a nitrogen atmosphere with moisture and oxygen content below 1 ppm.

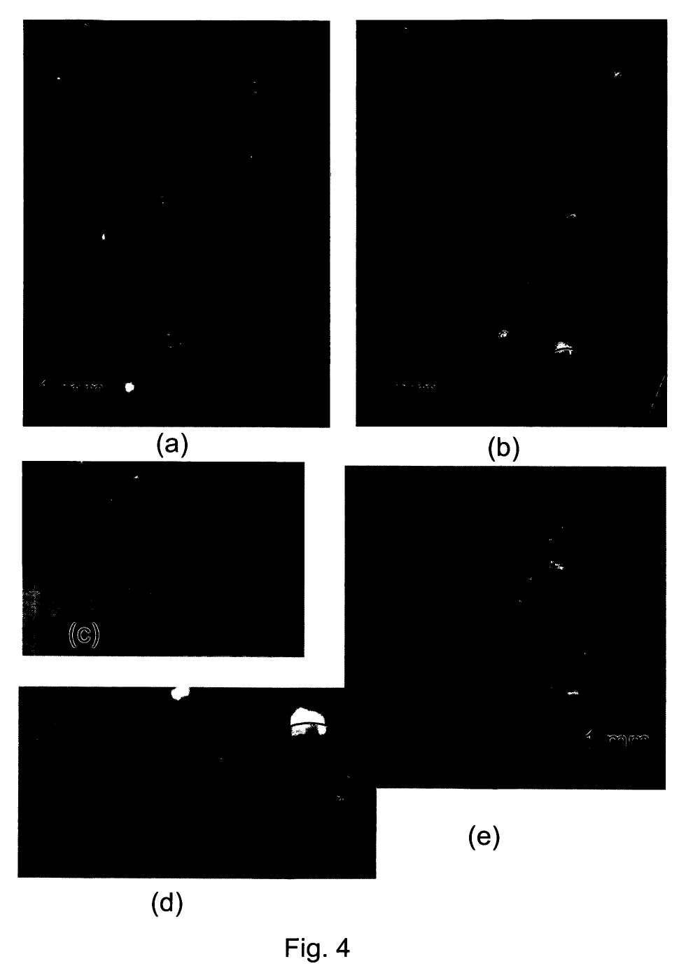

In carrying out the process, a layer of commercially available lithium nitride, which was preliminarily compacted into a pill of approximately 1.2 g, was placed at the bottom of the reaction vessel. On top of the lithium nitride pill 15.0 g of gallium was placed. After the crucible was filled with the charge, it was placed into the reactor 11. The reactor was evacuated to a vacuum level of 10⁻³ Torr, filled with nitrogen of 99.999% purity to a pressure of 0.1 MPa and then evacuated to a vacuum level of 10⁻³ Torr once more. After the evacuation, the furnace was filled with nitrogen of 99.999% purity to a pressure of 0.24 MPa. Then the crucible was heated by the furnace 13. During heating, part of the gallium reacted with lithium nitride, and gallium nitride source was formed at the bottom of the crucible as a result of this exchange reaction. At the same time, the lithium released during the exchange reaction, mixed with residual liquid gallium and formed a solvent for gallium nitride. After the completion of the reaction the temperature of the lower end of the reaction vessel was maintained at 800° C. and the temperature at the higher end of the solvent was maintained at 790° C., resulting in a temperature difference of 10° C. inside the solvent in the reaction vessel. Gallium nitride source started to dissolve in the created solvent, saturating the solution. To create a precipitation site, a piece of polycrystalline gallium nitride seed (FIG. 4) was immersed from the top into the solution when the temperature at the bottom reached 800° C. The growth conditions of the process were maintained for 65 hours following which, the polycrystalline seed was pulled out, the reactor was cooled to room temperature and the nitrogen pressure was allowed to be reduced to atmospheric.

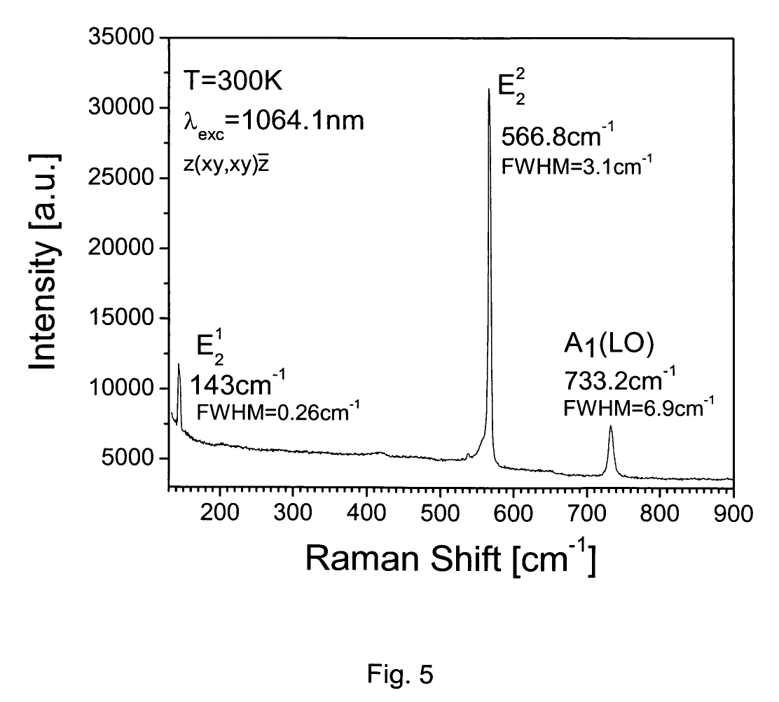

After cleaning the remaining solution from the seed, grown crystals of different orientations were found on the immersed portion of the seed. Most of the crystals formed as an epitaxial expansion of the crystallites of the aggregate (FIG. 4b,d). Some crystals were nucleated as twins on the very edge of the crystallites and developed as freestanding crystals (FIG. 4b,c). Most of the crystals grew epitaxially with the highest growth rates in the m-direction (FIG. 4d). All of the grown crystals were transparent and colorless, with well-defined hexagonal morphology. Micro-Raman measurements were performed at room temperature in the backscattering geometry, in order to characterize the structural quality of the sample. Examination of the grown crystals with μRS spectroscopy in the geometry showed the first-order allowed E₂¹, E₂² and A₁(LO) phonons with full width at half-maximum (FWHM) of 0.26, 3.1 cm⁻¹ and 6.9 cm⁻¹, respectively (FIG. 5). The sharp linewidths indicate high structural quality and low impurity concentrations [13].

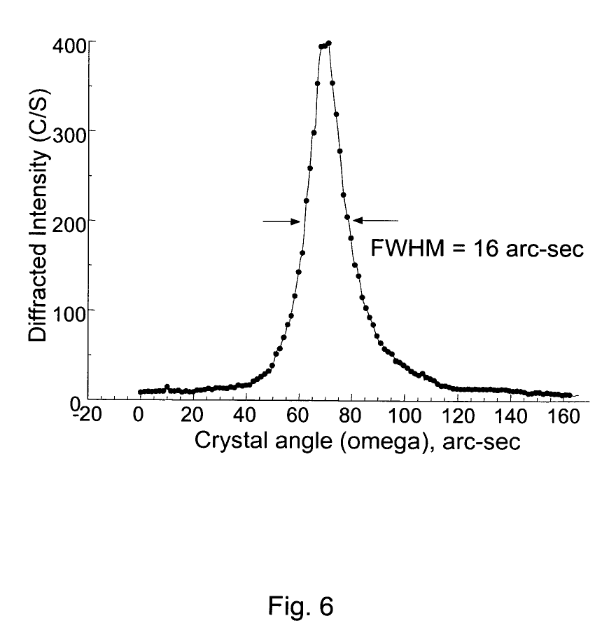

High crystallinity of the grown crystals was also confirmed by X-ray diffraction (XRD). FWHM of about 16 arc-sec was obtained for the (0004) rocking curve, excluding the additional dispersion and convolution corrections that would only enhance this number slightly (FIG. 6).

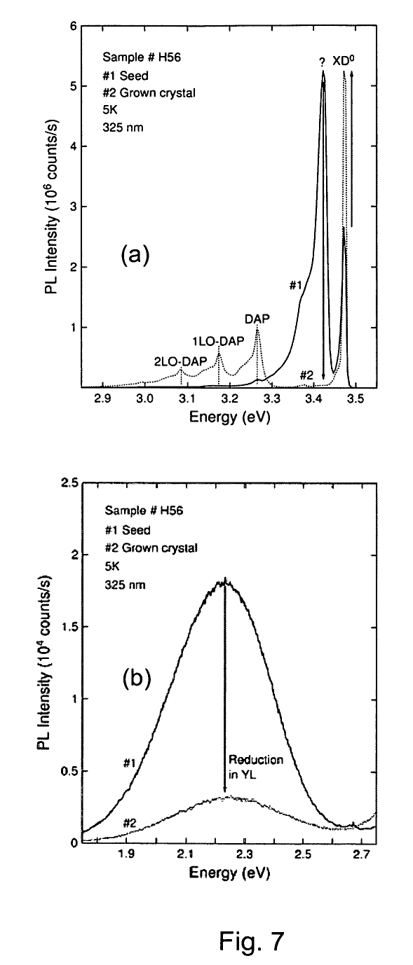

Low temperature PL (LT-PL) measurements were performed to evaluate the optical and electronic quality of the grown crystals. The position and intensity of the PL spectral peaks provide information about the type and concentration of the impurities, respectively. A dominant peak at 3.47 eV was observed in the spectra of crystals grown on polycrystalline aggregate seed (shown in FIG. 7a) and has been attributed to excitons bound to neutral shallow donor impurities (XD⁰ or D⁰X). High crystalline quality of the grown crystals was verified by improved XD⁰ line shape and linewidth, as compared with that of the seed. Reduction of the yellow band (YB) intensity, shown in FIG. 7b, is consistent with lower native defects and/or residual impurity concentration in the growth crystal, as compared with that of the seed.

### EXAMPLE 2

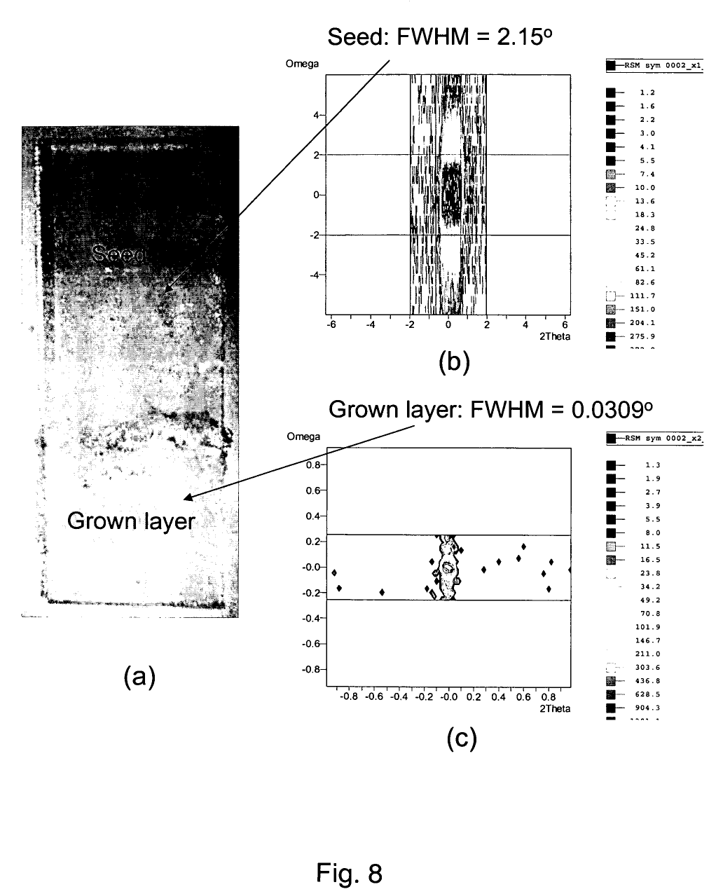

A layer of commercially available lithium nitride, which was preliminarily compacted into a pill of approximately 1.2 g was placed at the bottom of the reaction vessel. On top of the lithium nitride pill 14.0 g of gallium was placed. After the reaction vessel was filled with the charge, it was placed into the reactor 11. The reactor was evacuated to a vacuum level of 10⁻³ Torr, filled with nitrogen of 99.999% purity to a pressure of 0.1 MPa and then evacuated to a vacuum level of 10⁻³ Torr once more. After the evacuation, the furnace was filled with nitrogen of 99.999% purity to a pressure of 0.25 MPa. Then the crucible was heated by the furnace 13. During heating, part of the gallium reacted with lithium nitride, and gallium nitride source was formed as a result of this exchange reaction. At the same time, the lithium released during the exchange reaction mixed with residual liquid gallium and formed a solvent for gallium nitride. After the exchange reaction, the temperature of the lower end of the reaction vessel was maintained at 800° C. and the temperature at the higher end of the solvent was maintained at 790° C., thereby resulting in a temperature difference of 10° C. inside the solvent in the reaction vessel. Gallium nitride source started to dissolve in the created solvent, saturating the solution. A seed of quasi single crystal HVPE gallium nitride was partly immersed from the top into the solution when the temperature at the bottom reached 800° C. The growth conditions of the process were maintained for 126 hours following which, the seed was pulled out, the system was cooled to room temperature and the nitrogen pressure was allowed to be reduced to atmospheric. A homoepitaxial layer of gallium nitride single crystal was grown on the immersed part of the seed. The image of the gallium nitride seed with epitaxially grown gallium nitride layer is shown in FIG. 8a.

The nearly 100-μm thick homoepitaxially grown layer showed a two order-of-magnitude reduction in the full-width-at-half-maximum (FWHM) of the (0004) XRD diffraction peak. FWHM of the X-ray rocking curve measured on both the Ga- and N-face of the sample are 111 and 127 arcsec, respectively, compared to 2.15 degree and 2.45 degree for the Ga- and N-face of the GaN seed, respectively. It is unprecedented result of the improvement of the crystalline quality in the epitaxially grown GaN layer. FIG. 8b,c displays an omega-2theta space map of the symmetric (0004) reflection for the Ga-face (8b) as-received GaN seed and (8c) GaN grown crystal.

While presently preferred embodiments have been shown of the novel process, and of the several modifications discussed for the purpose of illustration, the foregoing description should not be deemed to be a limitation of the scope of the invention. Accordingly, persons skilled in this art will readily appreciate that various additional changes and modifications may be made without departing from the spirit of the invention as defined and differentiated by the following claims.

What is claimed is:

1. A process for making gallium nitride crystals comprising the steps of:
(a) charging a reaction vessel with a layer of one selected from the group consisting of a Group IA element nitride, a Group IIA element nitride, and combinations thereof;
(b) adding a layer of gallium in contact with the layer of the one selected from the group consisting of a Group IA element nitride, a Group IIA element nitride, and combinations thereof;
(c) placing the charged reaction vessel into a chamber;
(d) applying pressure to the reaction vessel to prevent dissociation or decomposition of the one selected from the group consisting of a Group IA element nitride, a Group IIA element nitride, and combinations thereof and the gallium nitride at a predetermined temperature;
(e) forming in situ a gallium nitride source by heating the charged reaction vessel to render the one selected from the group consisting of a Group IA element nitride, a Group IIA element nitride, and combinations thereof reacted with the gallium;
(f) forming in situ a solvent comprising the gallium and the one selected from the group consisting of a Group IA element nitride, a Group IIA element nitride, and combinations thereof released by an exchange reaction between the gallium and the one selected from the group consisting of a Group IA element nitride, a Group IIA element nitride, and combinations thereof;
(h) providing a temperature when formed gallium nitride will be dissolved in the formed solvent and providing a temperature difference in the solvent between the formed gallium nitride source and the growing single crystal gallium nitride in such a way that the growing single crystal nitride will be in the region of the reaction vessel which, under operating conditions, has a temperature near the low end of the temperature difference, and the formed gallium nitride source will be dissolved in the region of the reaction vessel which, under operating conditions, has a temperature near the high end of the temperature difference; and
(i) growing a single crystal gallium nitride under the driving force of the temperature difference.

2. The process of claim 1 wherein the heating is carried out to a liquefaction temperature of the solvent.

3. The process of claim 1 wherein the temperature difference is about 1-100° C. across the solvent thickness.

4. The process of claim 1 wherein the heating is conducted in an atmosphere comprising nitrogen gas at a pressure of about 0.1-20 MPa.

5. The process of claim 1 wherein the heating is conducted in an atmosphere comprising nitrogen gas at a pressure of about 0.2 MPa.

6. The process of claim 5 wherein growing a single crystal gallium nitride is conducted at temperature of about 700-850° C.

7. The process of claim 1 wherein the one selected from the group consisting of a Group IA element nitride, a Group IIA element nitride, and combinations thereof is lithium nitride.

8. The process of claim 1 further including the step of exposing a gallium nitride seed to the solvent whereby gallium nitride from the gallium nitride source precipitates on the seed.

9. The process of claim 8 wherein the gallium nitride seed is one selected from the group consisting of a single crystal gallium nitride, a polycrystalline gallium nitride, and a wafer of gallium nitride.

10. The process of claim 1 wherein the gallium nitride source comprises gallium nitride formed by the exchange reaction between the gallium and the one selected from the group consisting of a Group IA element nitride, a Group IIA element nitride, and combinations thereof or sintered or polycrystalline gallium nitride added to the charge.

11. The product of the process of claim 1.

12. A process for making a single crystal of gallium nitride comprising the steps of:
(a) charging a reaction vessel with a layer of one selected from the group consisting of a Group IA element nitride, a Group IIA element nitride, and combinations thereof;
(b) adding a layer of gallium combined with a Group IA or/and Group IIA element in contact with the layer of the one selected from the group consisting of a Group IA element nitride, a Group IIA element nitride, and combinations thereof;
(c) placing the charged reaction vessel into a chamber;
(d) applying pressure to the reaction vessel to prevent dissociation or decomposition of the one selected from the group consisting of a Group IA element nitride, a Group IIA element nitride, and combinations thereof and the gallium nitride at a predetermined temperature;
(e) forming in situ a gallium nitride source by heating the charged reaction vessel to render the one selected from the group consisting of a Group IA element nitride, a Group IIA element nitride, and combinations thereof reacted with the gallium;
(f) forming in situ a solvent comprising the gallium combined with a Group IA or/and Group IIA element and the one selected from the group consisting of a Group IA element, a Group IIA element, and combinations thereof released by the above mentioned exchange reaction between gallium and the one selected from the group consisting of a Group IA element nitride, a Group IIA element nitride, and combinations thereof;
(g) providing a temperature when formed gallium nitride will be dissolved in the formed solvent and providing a temperature difference in the solvent between the formed gallium nitride source and a growing single crystal gallium nitride in such a way that the growing single crystal nitride will be in the region of the reaction vessel which, under operating conditions, has a temperature near the low end of the temperature difference, and the formed gallium nitride source will be in the region of the reaction vessel which, under operating conditions, has a temperature near the high end of the temperature difference; and
(h) growing a single crystal gallium nitride under the driving force of the temperature difference.

13. The process of claim 12 wherein the heating is carried out to a liquefaction temperature of the solvent.

14. The process of claim 12 wherein the temperature difference is about 1-100° C. across the solvent thickness.

15. The process of claim 12 wherein the heating is conducted in an atmosphere comprising nitrogen gas at a pressure of about 0.1-20 MPa.

16. The process of claim 12 wherein the heating is conducted in an atmosphere comprising nitrogen gas at a pressure of about 0.2 MPa.

17. The process of claim 16 wherein growing a single crystal gallium nitride is conducted at temperature of about 700-850° C.

18. The process of claim 12 wherein the one selected from the group consisting of a Group IA element nitride, a Group IIA element nitride, and combinations thereof is lithium nitride.

19. The process of claim 12 further including the step of exposing a gallium nitride seed to the solvent whereby gallium nitride from the gallium nitride source precipitates on the seed.

20. The process of claim 19 wherein the gallium nitride seed is one selected from the group consisting of a single crystal gallium nitride, a polycrystalline gallium nitride, and a wafer of gallium nitride.

21. The process of claim 12 wherein the gallium nitride source comprises gallium nitride formed by the exchange reaction between the gallium and the one selected from the group consisting of a Group IA element nitride, a Group IIA element nitride, and combinations thereof and sintered or polycrystalline gallium nitride added to the charge.
